(19) United States
(12) Patent Application Publication
(10) Pub. No.: US 2026/0173975 A1
(43) Pub. Date: Jun. 18, 2026

(54) SEMICONDUCTOR PACKAGE AND METHOD OF FABRICATING THE SAME

(71) Applicant: Taiwan Semiconductor Manufacturing Company, Ltd., Hsinchu (TW)

(72) Inventors: Chun Chen, New Taipei City (TW); Chung-Kuang Lin, Hsinchu City (TW); Yung-Ping Chiang, Hsinchu County (TW)

(73) Assignee: Taiwan Semiconductor Manufacturing Company, Ltd., Hsinchu (TW)

(21) Appl. No.: 18/985,082

(22) Filed: Dec. 18, 2024

(51) Int. Cl. H01L 23/498; H01L 21/48; H01L 23/00; H01L 23/538; H01L 25/07

(52) U.S. Cl. CPC H10W 90/701; H10W 70/093; H10W 70/611; H10W 70/65; H10W 90/00; H10W 90/401; H10W 42/121; H10W 90/794

(57) ABSTRACT

A semiconductor package provided herein includes an interposer substrate; a semiconductor die bonded to a first side of the interposer substrate; a first fill material layer having a through hole; and a conductive terminal disposed in the through hole, the conductive terminal including a first conductor portion, a second conductor portion and a third conductor portion, the first conductor portion being between the second conductor portion and the interposer substrate, and the second conductor portion being between the first conductor portion and the third conductor portion, wherein a boundary between the first conductor portion and the second conductor portion is located between opposite surfaces of the first fill material.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. In an attempt to further increase circuit density, three-dimensional (3D) packaging methods have been investigated. For example, multiple dies are bonded (i.e. electrically coupled) together via electrical connections to form an integrated structure, and the integrated structure is further electrically coupled to package substrate via solder bumps, for example.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 6 schematically illustrate partial steps of fabricating a semiconductor package in accordance with some embodiments of the disclosure.

FIG. 7 schematically illustrate an enlarged portion VII in FIG. 6.

FIGS. 8-10 schematically illustrate partial steps of fabricating a semiconductor package in accordance with some embodiments of the disclosure.

FIG. 11 schematically illustrate a semiconductor package in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Generally, the present disclosure provides example embodiments relating to a semiconductor package (such as a three-dimensional (3D) package) and a method of fabricating the same. The provided semiconductor package includes a number of conductive terminals formed between the interposer substrate and the package substrate. The conductive terminals are encapsulated by two fill material layers, where one of the fill material layers is configured for maintain the flatness of the structure during the singulation process. Accordingly, the solder structures of the conductive terminals is prevented from being stained by the cutting debris during the singulation process, which ensures the property of the solder structure and thereby improves the yield and reliability of semiconductor packages. Some variations of the embodiments will be described. Throughout the various views and illustrative embodiments, like reference numbers are used to designate like elements.

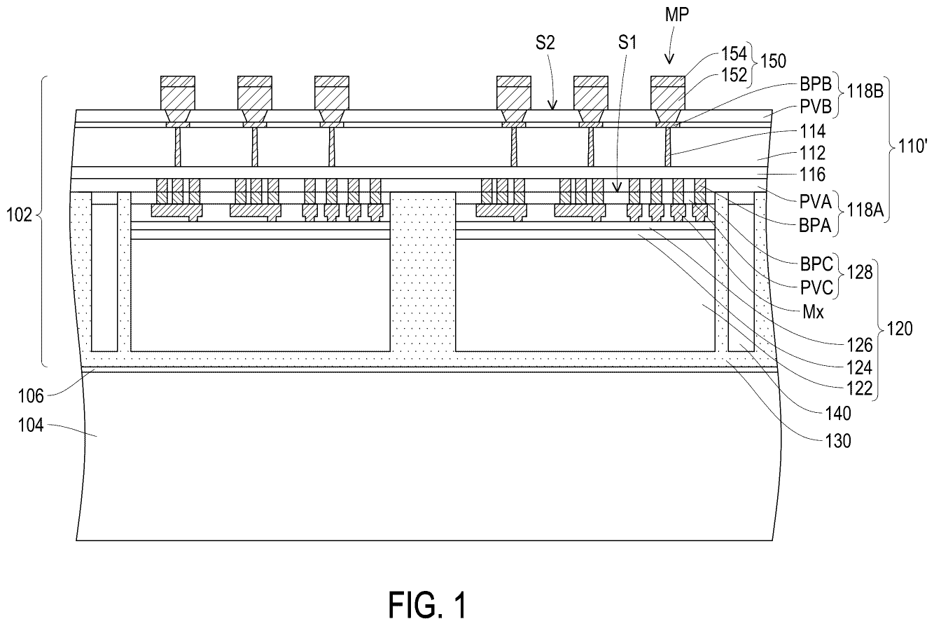

FIGS. 1 to 6 schematically illustrate partial steps of fabricating a semiconductor package in accordance with some embodiments of the disclosure. In FIG. 1, a wafer form structure 102 carried by a carrier 104 is provided. In some embodiments, the wafer form structure 102 includes a plurality of the unit structures shown in FIG. 1 and the unit structures are form integrally in a wafer form. For example, the wafer form structure 102 may include an interposer wafer 110′, semiconductor dies 120 bonded on the interposer wafer 110′, and an insulation encapsulant 130 disposed on the interposer wafer 110′ to surround and encapsulate the semiconductor dies 120. In some embodiments, the wafer form structure 102 may further include through insulation structures 140 disposed on the interposer wafer 110′ and surrounded by the insulation encapsulant 130. In some embodiments, the wafer form structure 102 may be temporally attached onto the carrier 104 through a releasing material 106.

In some embodiments, the interposer wafer 100′ includes a substrate 112, through substrate conductors 114, an interconnect circuit structure 116, a bonding layer 118A and another bonding layer 118B. The substrate 112 may be a silicon substrate, but the disclosure is not limited thereto. Each of the through substrate conductors 114 extends between a first side S1 of the interposer wafer 110′ and a second side S2 of the interposer wafer 110′ to pass through the substrate 112. The interconnect circuit structure 116 is disposed on the substrate 110 at the first side S1 of the interposer wafer 110′ and includes metal features (not shown) embedded in dielectric material to establish various electrically communication paths. The bonding layer 118A disposed at the first side S1 of the interposer wafer 110′ includes bonding pads BPA embedded in the passivation layer PVA. In some embodiments, the bonding pads BPA and the passivation layer PVA may be co-leveled at the first side S1. In addition, the bonding pads BPA are electrically connected to the interconnect circuit structure 116. The bonding layer 118B disposed at the second side S2 of the interposer wafer 110′ includes bonding pads BPB and the passivation layer PVB disposed on the substrate 112. The passivation layer PVB has openings exposing the bonding pads BPB. In some embodiments, under bump metals (UBM) may be further disposed on the passivation layer PVB and connected to the bonding pads BPB, but the disclosure is not limited thereto. In the interposer wafer 110′, the through substrate conductors 114 may be respectively electrically connected to the bonding pads BPB at the second side S2 and electrically connected to the interconnect circuit structure 116 at the first side S1.

Each of the semiconductor die 120 includes a semiconductor substrate 122, a device layer 124, an interconnect circuit structure 126 and a bonding layer 128. The device layer 124 is schematically illustrated as a layer in FIG. 1, and in some embodiments, the device layer 124 includes circuit devices formed on/in the semiconductor substrate 122. The circuit devices in the device layer 124 include active devices (e.g., transistors or the like) and passive devices (e.g., resistors, capacitors, inductors, or the like). The interconnect circuit structure 126 is disposed on the device layer 124 to form electrical transmission paths for the circuit devices in the device layer 124. The bonding layer 128 includes bonding pads BPC embedded in a passivation layer PVC. In some embodiments, the interconnect circuit structure 126 includes redistribution conductive features Mx and the bonding pads BPC in the bonding layer 128 are electrically connected the redistribution conductive features Mx.

The bonding layer 128 of the semiconductor die 120 is bonded to the bonding layer 118A of the interposer wafer 110′. In some embodiments, the bonding pads BPA in the bonding layer 118A is in contact with the bonding pads BPC in the bonding layer 128 and the passivation layer PVA in the bonding layer 118A is in contact with the passivation layer PVC of the bonding layer 128. The semiconductor die 120 may be bonded to the interposer wafer 110′ through a metal-to-metal and dielectric-to-dielectric bonding technique, but the disclosure is not limited thereto. In some embodiments, the semiconductor die 120 may be bonded to the interposer wafer 110′ through alternative bonding techniques such as bonded with micro bumps, or the like.

The insulation encapsulant 130 is disposed on the first side S1 of the interposer wafer 110′ and surrounds the semiconductor dies 120. The insulation encapsulant 130 may be thicker than the semiconductor dies 120 and is attached to the carrier 104. The through insulation structures 140 helps to ensure the mechanical strength of the wafer form structure 102. In some embodiments, the through insulation structures 140 are optionally omitted.

In FIG. 1, conductive terminals 150 are formed to be disposed on the second side S2 of the interposer wafer 110′. For example, a first conductor portion 152 of each conductive terminal 150 and a second conductor portion 154 of each conductive terminal 150 are sequentially formed on the corresponding bonding pad BPB. In some embodiments, the formation of the conductive terminals 150 includes forming a patterned mask layer (not shown) on the passivation layer PVB. The patterned mask layer includes through holes corresponding to the openings of the passivation layer PVB to expose the bonding pads BPB. Then, a metal material or a conductive material is deposited on the bonding pads BPB. The metal material or the conductive material fills the opening of the patterned mask layer to certain height to form a pillar-like conductive feature. The deposition of the metal material or the conductive material may include sputtering, printing, electro plating, electroless plating, CVD, or the like. In some embodiments, a first metal/conductive material is deposited on the bonding pads BPB to form the first conductor portion 152 and a second metal/conductive material is further deposited/formed on the first conductor portion 152 to form the second conductor portion 154. Thereafter, the pattern mask layer is removed from the passivation layer PVB to obtain the first conductor portion 152 and the second conductor portion 154 of each conductive terminal 150 shown in FIG. 1.

The first conductor portion 152 and the second conductor portion 154 stacking on the first conductor portion 152 form a metal pillar MP having substantially vertical sidewalls or tapered linear sidewalls according to the shapes of the openings in the patterned mask layer. In some embodiments, the first conductor portion 152 of the metal pillar MP may be solder free and the second conductor portion 154 of the metal pillar MP includes a solder material. In some embodiments, the first conductor portion 152 may include copper, aluminum, gold, nickel, silver, palladium, tin, the like, or any combination thereof, and the second conductor portion 154 may include nickel, tin, tin-lead, gold, silver, palladium, nickel-palladium-gold, nickel-gold, the like, or any combination thereof. In some embodiments, one or more further conductor layer may be formed between the first conductor portion 152 and the second conductor portion 154.

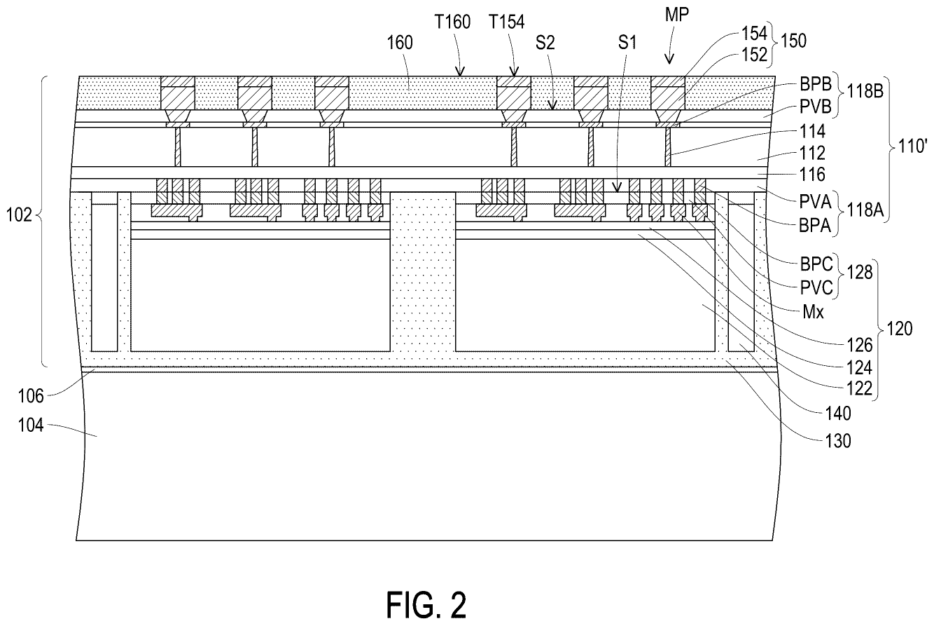

Referring to FIG. 2, a first fill material layer 160 is formed on the interposer wafer 110′ to surround the first conductor portion 152 and the second conductor portion 154 of the metal pillar MP. The material of the first fill material layer 160 include dielectric material such as polyimide (PI), molding compound material, photo resist material, or the like. The first fill material layer 160 may be formed by coating process to have a thickness that is not less than the height of the metal pillar MP. In some embodiments, the dielectric material for forming the first fill material layer 160 is coated on the interposer wafer 110′ and a planarization process such as grinding or the like is performed to render the first fill material layer 160 and the metal pillar MP to be co-leveled. Accordingly, a distal surface T154 of the second conductor portion 154 away from the interposer wafer 110′ and a distal surface T160 of the first fill material layer 160 away from the interposer wafer 110′ are co-leveled. The wafer form structure 102 has a flat surface at the second side S2 of the interposer wafer 110′.

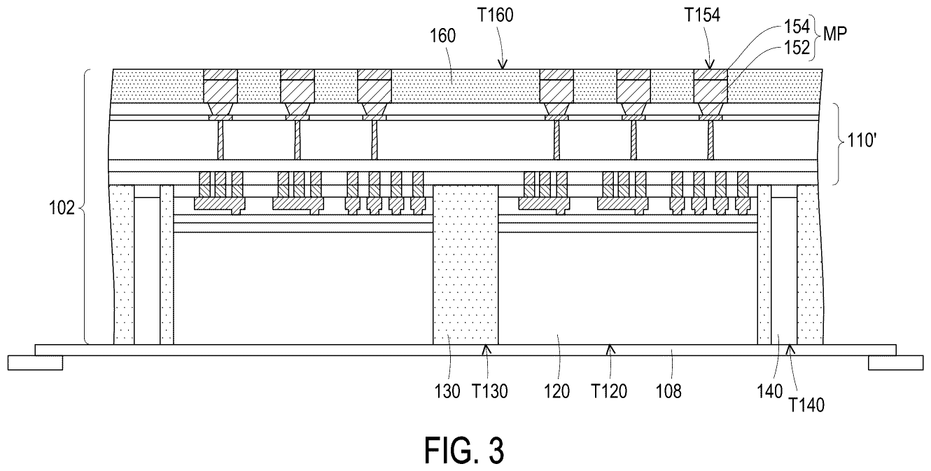

After forming the first fill material layer 160, the carrier 104 is removed from the wafer form structure 102. In some embodiments, the carrier 104 is de-bonded from the wafer form structure 102 by transferring the wafer form structure 102 to a carrier frame (not shown) in a manner that the distal surface T154 of the second conductor portion 154 and the distal surface T160 of the first fill material layer 160 are supported by the carrier frame (not shown), and de-bonding the carrier 104 from the wafer form structure 102 by performing a laser irradiation to the releasing material 106 to decompose the releasing material 106. Then, a portion of the insulation encapsulant 130 exceeding the semiconductor dies 120 and the through insulation structures 140 is removed after the carrier 104 is separated from the wafer form structure 102 and the wafer form structure 102 is transferred to another carrier frame 108 as shown in FIG. 3.

In FIG. 3, a distal surface T140 of the through insulation structure 140 away from the interposer wafer 110′ and a distal surface T130 of the insulation encapsulant 130 away from the interposer wafer 110′ are co-leveled. In some embodiments, a distal surface T120 of the semiconductor die 120 away from the interposer wafer 110′ is also co-leveled with the distal surface T130 of the insulation encapsulant 130. The wafer form structure 102 is oriented in a manner that the distal surface T120 of the semiconductor die 120, the distal surface distal surface T130 of the insulation encapsulant 130, and distal surface T140 of the through insulation structures 140 are supported by/in contact with the carrier frame 108. Simultaneously, the distal surface T160 of the first fill material layer 160 and the distal surface T154 of the second conductor portion 154 of the metal pillar MP are exposed.

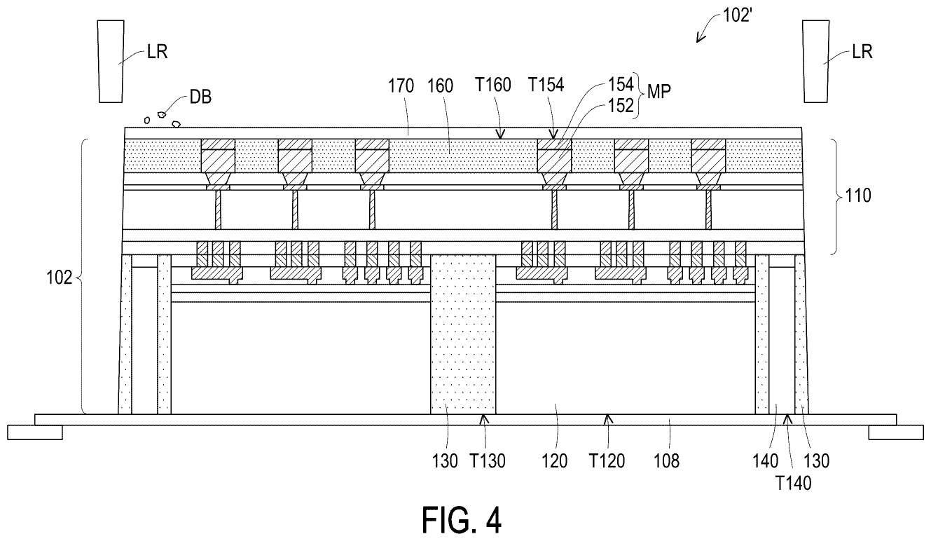

In FIG. 4, a protection film 170 is formed on the wafer form structure 102 carried by the carrier frame 108. In some embodiments, the protection film 170 is coated on the wafer form structure 102 by a spin coating or the like. The protection film 170 covers the distal surface T154 of the second conductor portion 154 of the metal pillar MP and the distal surface T160 of the first fill material layer 160. The distal surface T154 and the distal surface T160 are substantially co-leveled so that the protection film 170 is coated on a substantially flat surface formed by the distal surface T154 and the distal surface T160, which ensures the coverage and the evenness of the protection film 170. For examples, the protection film 170 completely covers the distal surface T154 in an even thickness. Accordingly, the protection film 170 has a sufficient thickness over the metal pillar MP to provide the protection effect.

In FIG. 4, a singulation process is performed on the wafer form structure 120 to divide the wafer form structure 120 into one or more individual package unit 120'. The singulation process includes irradiating the wafer form structure 102 by a laser beam LR along a prescribed processing path to cut the interposer wafer 110′ into an interposer substrate 110. The singulation process further includes performing a die sawing step along the processing path of the laser beam LR to cut the insulation encapsulant 130 and obtain the individual package unit 102′. During the singulation process including the laser irradiating step and the die sawing step, the cutting debris DB splits. As shown in FIG. 4, the protection film 170 has a sufficient and even thickness over the metal pillar MP and the first fill material layer 160 so that the debris DB would not stain on the metal pillar MP or the first fill material layer 160. After the singulation process, the protection film 170 is subsequently removed by a cleaning process such as water clean or the like.

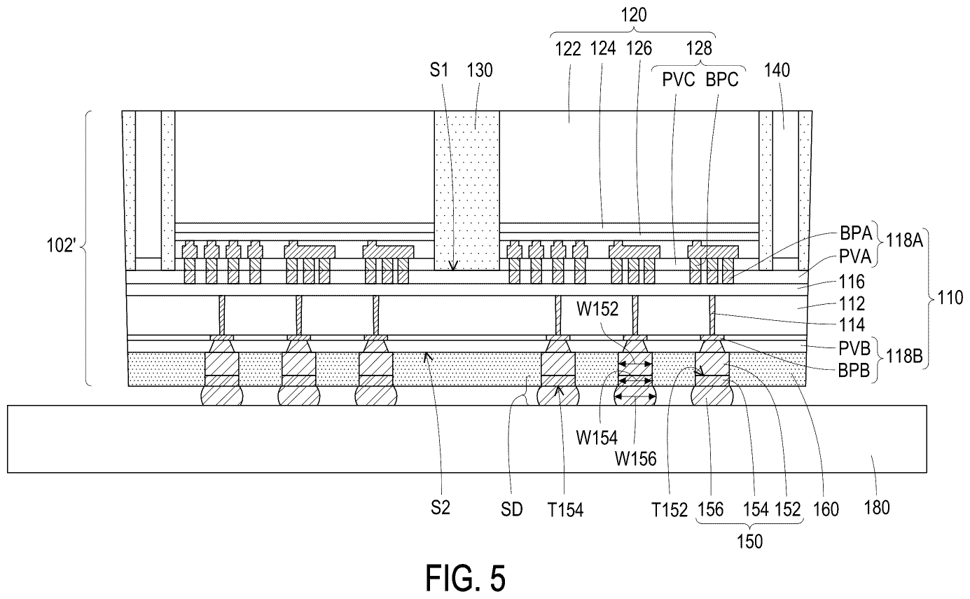

In FIG. 5, a third conductor portion 156 is formed and the package unit 102′ is bonded onto a package substrate 180 through the conductive terminal 150 that includes the first conductor portion 152, the second conductor portion 154 and a third conductor portion 156. In the embodiment, the package unit 102′ includes the interposer substrate 110, the semiconductor dies 120 bonded to the first side S1 of the interposer substrate 110, the insulation encapsulant 130 surrounding the semiconductor dies 120 and the through insulation structures 140 penetrating through the insulation encapsulant 130.

In some embodiments, the bonding process includes at least forming a solder material on the package substrate 160 or on the second conductor portion 154 and assembling the package substrate 160 and the package unit 102 so that the solder material is in contact with the second conductor portion 154 and the package substrate 160. The solder material is then reflowed to form the third conductor portion 156 of the conductive terminal 150. The third conductor portion 156 and the second conductor portion 154 both include a solder material so that the third conductor portion 156 and the second conductor portion 154 may be softened during the reflow process. In some embodiments, the second conductor portion 154 may be mixed with the third conductor portion 156 after the reflow process so that the boundary between the second conductor portion 154 and the third conductor portion 156 may not easily be observed.

In some embodiments, the second conductor portion 154 and the third conductor portion 156 may form a solder structure SD disposed between the first portion 152 and the package substrate 180. In the embodiment, the distal surface T154 of the second conductor portion 154 is cleaned without being stained by the debris DB generated during the singulation step shown in FIG. 4. Accordingly, the attachment between the second conductor portion 154 and the third conductor portion 156 and the electric property of the solder structure SD formed by the second conductor portion 154 and the third conductor portion 156 are ensured.

The second conductor portion 154 is limited by the first fill material layer 160 so that the shape of the second conductor portion 154 remains the same before and after the reflow process. The third conductor portion 156 is not limited so that the third conductor portion 156 may have a bumpy shape after the reflow process. For example, the sidewall of the third conductor portion 156 is curved to have a curvature greater than a sidewall of the second conductor portion 154 and a sidewall of the first conductor portion 152, but the disclosure is not limited thereto. In some embodiments, a width W156 of the third conductor portion 156 is greater than a width W154 of the second conductor portion 154 since the third conductor portion 156 is not limited during the reflow process. In some embodiments, the width W152 of the first conductor portion 152 and the width W154 of the second conductor portion 154 are corresponded. For example, the width W152 of the first conductor portion 152 and the width W154 of the second conductor portion 154 are substantially identical or at least identical at the boundary between the first conductor portion 152 and the second conductor portion 154, i.e. the distal surface T152 of the first conductor portion 152 away from the interposer substrate 110.

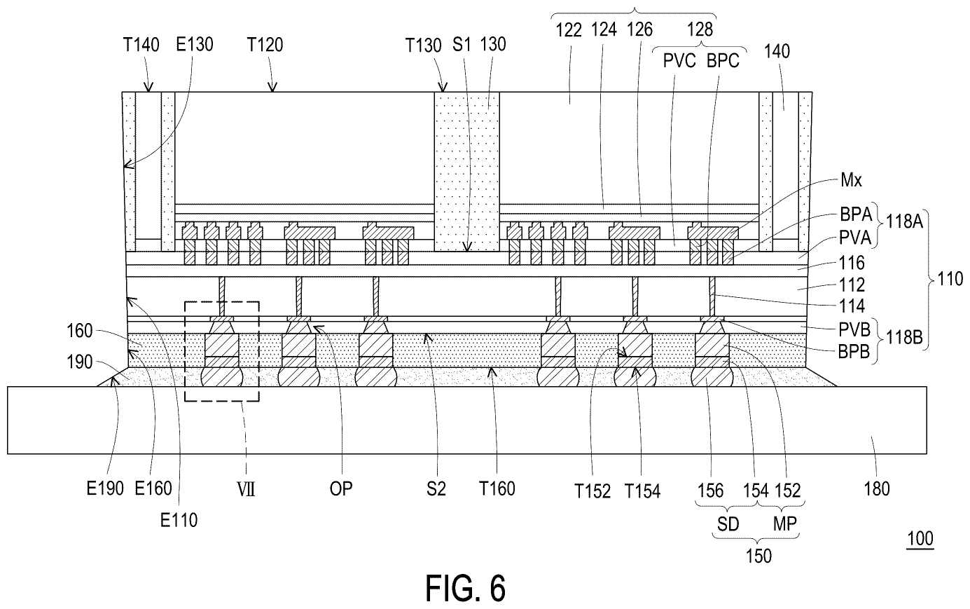

In FIG. 6, a second fill material layer 190 is formed after bonding the interposer substrate 110 to the package substrate 180 to obtain a semiconductor package 100, wherein the second fill material layer 190 fills a space between the package substrate 180 and the first fill material layer 160 and laterally surrounds/encapsulates the third conductor portion 156. The second fill material layer 190 may be formed by a capillary flow process of an insulating material, such as a polymer material. The second fill material layer 190 may reduce stress resulting from the reflowing of the second conductor portion 154 and the third conductor portion 156 and protect the third conductor portion 156. A material of the second fill material layer 190 may be different from a material of the first fill material layer 160. In some embodiments, a sidewall E190 of the second fill material layer 190 is tapered exceeding the first fill material layer 160. For example, the second fill material layer 190 may have a narrower width at the level adjacent to the first fill material layer 160 and a wider width at the level adjacent to the package substrate 180. In addition, the second fill material layer 190 has a wider width than the first fill material layer 160 and exceeds the first fill material layer 160. In some embodiments, a portion of the second fill material layer 190 may cover a portion of the sidewall of the first fill material layer 160.

The semiconductor package 100 includes an interposer substrate 110, one or more semiconductor die 120, conductive terminals 150, and a package substrate 180. The semiconductor die 120 is bonded to a first side S1 of the interposed substrate 110 while a second side S2 of the interposer substrate 110 is bonded to the package substrate 180, in which the second side S2 is opposite to the first side S1. The interposer substrate 110 may support multiple semiconductor dies 120 and interposed between the semiconductor dies 120 and the package substrate 180 to provide the electric connection between the semiconductor dies 120 and the package substrate 180. In some embodiments, the interposer substrate 110 may also provide the electric connection between the semiconductor dies 120. In other words, the interposer substrate 110 accomplishes the electric connection between various components of the semiconductor package 100 in the thickness direction, the lateral direction, and/or both.

The interposer substrate 110 includes a substrate 112, through substrate conductors 114, an interconnect circuit structure 116, a bonding layer 118A and another bonding layer 118B. Each of the through substrate conductors 114 extends through the substrate 112. The interconnect circuit structure 116 is disposed on the substrate 112 at the first side S1 of the interposer substrate 110 and is electrically connected to the through substrate conductors 114. The bonding layer 118A is disposed on and electrically connected to the interconnect circuit structure 116. The bonding layer 118B is disposed on the substrate 112 at the second side S2 of the interposer substrate 110. The bonding layer 118A and the bonding layer 118B are located at opposite sides of the substrate 112.

The substrate 112 may be a silicon substrate. The through substrate conductors 114 are formed embedded in the substrate 112 to provide an electrical transmission passing through the substrate 112. In some embodiments, the through substrate conductors 114 are through substrate vias which has pillar-like shapes and are made of conductive material such as metal. In some embodiments, each of the through substrate conductors 114 may include a liner layer and metal fill surrounded by the liner layer. The interconnect circuit structure 116 includes metal features (not shown) embedded in a dielectric structure to form electric transmission paths, in which the dielectric structure may include multiple dielectric layers. The through substrate conductors 114 may be electrically connected to at least a portion of the metal features of the interconnect circuit structure 116.

The bonding layer 118A includes bonding pads BPA surrounded by a passivation layer PVA. In some embodiments, a portion of the metal features (not shown) of the interconnect circuit structure 116 provides the vertical electric transmission between the through substrate conductors 114 and the bonding pads BPA and another portion of the metal features (not shown) of the interconnect circuit structure 116 provides the lateral electric transmission between the bonding pads BPA. For example, the through substrate conductors 114 are electrically connected to the bonding pads BPA through at least a portion of the metal features (not shown) of the interconnect circuit structure 116. In addition, at least a portion of the bonding pads BPA is electrically connected to each other through the metal features (not shown) of the interconnect circuit structure 116 to provide the required electric transmission.

The bonding layer 118B includes bonding pads BPB and a passivation layer PVB disposed over the bonding pads BPB. The bonding pads BPB are electrically connected to the through substrate conductors 116. As such, the bonding layer 118A, the interconnect circuit structure 116, the through substrate conductor 114 and the bonding layer 118B formed continuously electrical transmission paths between the first side S1 of the interposer substrate 110 and the second side S2 of the interposer substrate 110. The passivation layer PVB includes openings OP revealing the bonding pads BPB so that the conductive terminals 150 are in contact with the bonding pads BPB through the openings OP.

The semiconductor dies 120 are bonded to the bonding layer 118A located at the first side S1 of the interposer substrate 110. In some embodiments, each of the second semiconductor dies 120 includes a semiconductor substrate 122, a device layer 124 formed in/on the semiconductor substrate 122, an interconnect circuit structure 126 disposed on the device layer 124, and a bonding layer 128 disposed on the interconnect circuit structure 126. The device layer 124 includes active devices (e.g., transistors or the like), passive devices (e.g., resistors, capacitors, inductors, or the like), or a combination thereof to established the circuitry with required function. The interconnect circuit structure 126 includes interconnect wirings/vias (not shown) embedded in multiple dielectric layers (not shown) to electrically connect the device layer 124 to the bonding layer 118A. The bonding layer 128 includes bonding pads BPC embedded in a passivation layer PVC and the bonding pads BPC are electrically connected to the redistribution conductive features Mx in the interconnect circuit structure 126. Each of the semiconductor die 120 is bonded to and electrically connected to the interposer substrate 110 thought the bonding pads BPC of the bonding layer 126 in contact with the bonding pads BPA of the bonding layer 118A and the passivation layer PVC of the bonding layer 126 in contact with the passivation layer PVA of the bonding layer 118A. Therefore, each of the semiconductor die 120 is bonded to the interposer substrate 112 through a metal-to-metal and dielectric-to-dielectric bonding technique.

At the second side S2 of the interposer substrate 110, the bonding layer 118B of the interposer substrate 110 is bonded to the package substrate 180 through the conductive terminals 150. Each of the conductive terminals 150 includes a first conductor portion 152, a second conductor portion 154 and a third conductor portion 156 sequentially stacked on the interposer substrate 110. The first conductor portion 152 is between the second conductor portion 154 and the interposer substrate 110, and the third conductor portion 156 is between the first conductor portion 152 and the package substrate 180. The conductive terminals 150 extend into the openings OP of the passivation layer PVB and are in contact with the bonding pads BPB. In addition, the package substrate 180 may include conductive features (not shown) revealed at the surface and the conductive terminals 150 is in contact with the conductive features of the package substrate 180.

The first conductor portion 152 may be solder free while the second conductor portion 154 and the third conductor portion 156 may include a solder material. Therefore, the first conductor portion 152 is made of a conductive material different from the second conductor portion 154 and the third conductor portion 156. In some embodiments, the second conductor portion 154 and the third conductor portion 156 may include a common material, but the disclosure is not limited thereto. In some embodiments, one or more layer of conductive material may be interposed between the first conductor portion 152 and the second portion 154. For example, the first conductor portion 152 may be made of Cu, the second conductor portion 154 may be made of Sn, and a layer of Ni may be interposed between the first conductor portion 152 and the second conductor portion 154. In some embodiments, the second conductor portion 154 and the third conductor portion 156 are respectively fabricated before and after the singulation process, and the interposer substrate 110 is bonded to the package substrate 180 by contacting the second conductor portion 154 to the third conductor portion 156.

The semiconductor package 100 further includes an insulation encapsulant 130 and through insulation structures 140. The insulation encapsulant 130 is disposed at the first sides S1 of the interposer substrate 110 and laterally surrounds the semiconductor dies 120. The through insulation structures 140 are embedded in the insulation encapsulant 130 and located at a periphery of the semiconductor package 100. In some embodiments, a distal surfaces T120 of the semiconductor dies 120 away from the interposer substrate 110, the distal surface T130 of the insulation encapsulant 130 away from the interposer substrate 110 and the distal surfaces T140 of the through insulation structures 140 are co-leveled. Accordingly, the semiconductor package 100 may have a flat surface opposite to the package substrate 180.

In addition, the semiconductor package 100 further includes a first fill material layer 160, and a second fill material layer 190. The first fill material layer 160 and the second fill material layer 190 are disposed between the interposer substrate 110 and the package substrate 180. The first fill material layer 160 is disposed between the interposer substrate 110 and the second fill material layer 190 and the second fill material layer 190 is disposed between the first fill material layer 160 and the package substrate 180. The first fill material layer 160 and the second fill material layer 190 may be of different materials. The first conductor portion 154 and the second conductor portion 156 of the conductive terminal 150 is surrounded by the first fill material layer 160 and the third conductor portion 156 of the conductive terminal 150 is surrounded by the second fill material layer 190.

In some embodiments, a sidewall E110 of the interposer substrate 110, a sidewall E130 of the insulation encapsulant 130 and a sidewall E160 of the first fill material layer 160 are corresponded. In some embodiments, the sidewall E110, the sidewall E130 and the sidewall E160 are aligned along a linear path, in which the linear path may be parallel to the thickness direction, or oblique to the thickness direction. The sidewall E190 of the second fill material layer 190 is not aligned with the sidewall E110, the sidewall E130 and the sidewall E160. In some embodiments, an included angle between the sidewall E190 and the sidewall E160 is greater than an included angle between the sidewall E160 and the sidewall E110 and an included angle between the sidewall E110 and the sidewall E130. In some embodiments, the sidewall E130, the sidewall E110 and the sidewall E160 form a tapered edge in a way that the width of the structure gradually shrinks toward the package substrate 180 and the sidewall E190 form another tapered edge in a way that the width of the structure gradually expands toward the package substrate 180. In some embodiments, a portion of the second fill material layer 190 may cover a lower portion of the first fill material layer 160.

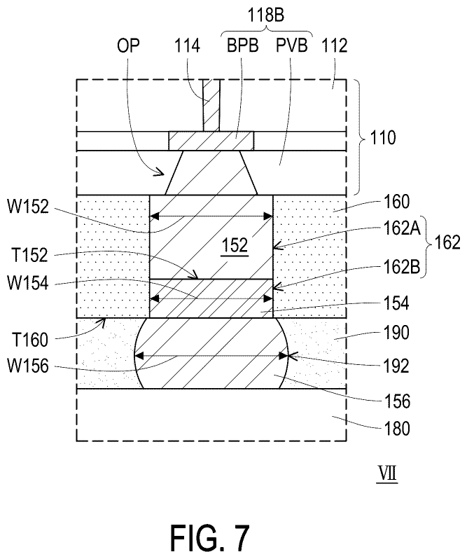

FIG. 7 schematically illustrate an enlarged portion VII in FIG. 6. As shown in FIG. 6 and FIG. 7, the first conductor portion 152 and the second conductor portion 154 are stacked in the thickness direction to form a metal pillar MP and the third portion 156 is disposed at the terminal of the metal pillar MP. The third portion 156 may have a bumpy structure that is distinct from the metal pillar MP. In some embodiments, a width W156 of the third conductor portion 156 may be greater than a width W154 of the second conductor portion 154 and a width W152 of the first conductor portion 152. In some embodiments, the width W156 of the third conductor portion 156 varies along the thickness direction. In some embodiments, the width W156 of the third conductor portion 156 is greater at the middle part than at the terminal part. In some embodiments, the width changes of different third conductor portions 156 may be different so that the shapes of different conductor portions 156 are different. In some embodiments, the metal pillars MP may have predetermined shapes without obvious variation. For example, a width of each metal pillar MP is substantially constant, or gradually changed along the thickness direction.

The first fill material layer 160 laterally surrounds the metal pillar MP of the conductive terminal 150 and the second fill material layer 190 laterally surrounds the third conductor portion 156 of the conductive terminal 150. A boundary between the first fill material layer 160 and the second fill material layer 190/the solder structure SD, i.e. the distal surface T152 of the first conductor portion 152 away from the interposer substrate 110 is between opposite surfaces of the first fill material layer 160 and more adjacent to the interposer substrate 110 than the distal surface T160 of the first fill material layer 160 away from the interposer substrate 110.

In some embodiments, the second conductor portion 154 and the third conductor portion 156 may be made of similar or substantially the same material and may be mixed to form a solder structure SD and a portion of the solder structure SD between the level of the distal surface T160 and the level of the distal surface T152 is considered as the second conductor portion 154 while another portion of the solder structure SD between the level of the distal surface T160 and the package substrate 180 is considered as the third conductor portion 156. That is, the solder structure SD includes the second conductor portion 154 and the second conductor portion 156, and a boundary between the second conductor portion 154 and the third conductor portion 156 may be co-leveled with the distal surface T160 of the first fill material layer 160 away from the interposer substrate 110. The solder structure SD is formed by the second conductor portion 154 surrounded by the first fill material layer 160 and the third conductor portion 156 surrounded by the second fill material layer 190. In some embodiments, a portion of the solder structure SD, i.e. the second conductor portion 154, laterally encapsulated by the first fill material layer 160 is narrower than another portion of the solder structure SD, i.e. the third conductor portion 156, laterally encapsulated by the second fill material layer 190 in a lateral dimension.

In some embodiments, the first fill material layer 160 include a through hole 162 accommodating the metal pillar MP and the through hole 162 of the first fill material layer 160 has a first segment 162A in contact with the first conductor portion 152 and a second segment 162B in contact with the second conductor portion 154. The width W152 of the first conductor portion 152 is corresponding to the width W154 of the second conductor portion 154. In some embodiments, the width W152 and the width W154 may be substantially identical and the through hole 162 may have a constant width along the thickness direction. In some embodiments, the width W152 proximate to the level of the boundary between the first conductor portion 152 and the second conductor portion 154 is identical to the width W154 proximate to the level of the boundary between the first conductor portion 152 and the second conductor portion 154. In some embodiments, the width W152 is changed along the thickness direction and the width W154 is changed along the thickness direction following the width change of the width W152, so that the through hole 162 may have a tapered sidewall and the tapered sidewall does not include an obvious change between the first segment 162A and the second segment 162B.

The second fill material layer 190 has the through hole 192 accommodating the third conductor portion 156. The third conductor portion 156 has a bumpy structure exceeding the second conductor portion 154 and the through hole 192 has a curved sidewall. The third conductor portion 156 is shaped by the reflow process described in the step FIG. 5. In some embodiments, the third portion 156 has a curved sidewall. In some embodiments, a width change of the third conductor portion 156 is greater than the first conductor portion 152 and the second conductor portion 154. In some embodiments, the width W156 of the third portion 156 is changed along the thickness in a manner that the width W156 is greater at the middle part than at the terminal part. In some embodiments, the shape of the third conductor portion 156 may be asymmetric. In some embodiments, different third conductor portion 156 have different shapes.

The second conductor portion 154 and the third conductor portion 156 both include a solder material. During the reflow process depicted in FIG. 5, the second conductor portion 154 is limited by the first fill material layer 160 so that the second conductor portion 154 does not have a bumpy structure. In addition, as described in FIG. 4, the second conductor portion 154 is not stained by cutting debris DB so that the joint between the second conductor portion 154 and the third conductor potion 156 is ensured, which helps to provide desirable bonding effect. For example, the second conductor portion 154 is firmly connected to or properly mixed with the third conductor portion 156 to provide good electric conduction between the second conductor portion 154 and the third conductor portion 156. Accordingly, the semiconductor package 100 may have desirable yield rate and quality.

In some embodiments, the conductive terminals 150 formed in the semiconductor package 100 may be arranged in various pitches and may have different sizes. In some embodiments, a portion of the conductive terminals 150 configured for transmitting electrical signals may have a smaller size than another portion of the conductive terminals 150 configured for transmitting electric power. In some embodiments, a portion of the conductive terminals 150 configured for transmitting electrical signals may be arranged in a smaller pitch than another portion of the conductive terminals 150 configured for transmitting electric power.

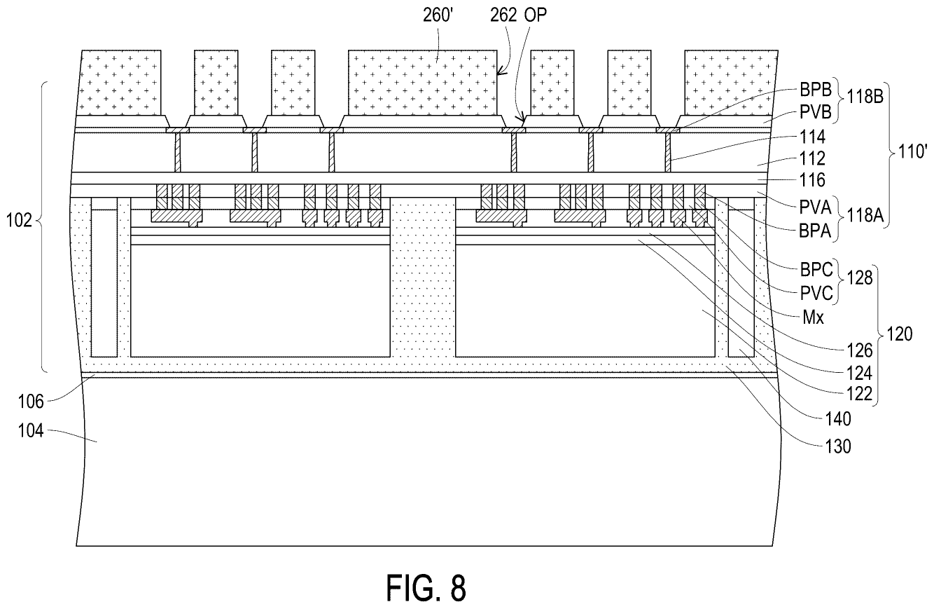

FIGS. 8-10 schematically illustrate partial steps of fabricating a semiconductor package in accordance with some embodiments of the disclosure. In FIG. 8, a wafer form structure 102 is carried by a carrier 104 and is similar to the wafer form structure 102 depicted in FIG. 1. Specifically, the wafer form structure 102 includes an interposer wafer 110′, semiconductor dies 120, and insulation encapsulant 130 and through insulation structures 140. The interposer wafer 110′ includes a substrate 112, through substrate conductors 114, an interconnect circuit structure 116, a bonding layer 118A including bounding pads BPA and a passivation layer PVA and another bonding layer 118B including bounding pads BPB and a passivation layer PVB. Each of the semiconductor dies 120 includes a semiconductor substrate 122, a device layer 124, an interconnect circuit structure 126 and a bonding layer 128 including bounding pads BPC and a passivation layer PVC. The descriptions for the wafer form structure 102 depicted in FIG. 1 are applicable to the present embodiment shown in FIG. 8 and are not reiterated here.

A thick mask layer 260′ is formed on the interposer wafer 110′ and the thick mask layer 260′ is a patterned layer made of a dielectric material such as polyimide (PI), photoresist material or the like. The thick mask layer 260′ is patterned to have through holes 262 corresponding to the bonding pads BPB of the interposer wafer 110′. The passivation layer PVB of the interposer wafer 110′ has openings OP over the bonding pads BPB and the through holes 262 respectively communicates the openings OP so that the bonding pads BPB are at least partially revealed without being covered by the passivation layer PVB and the thick mask layer 260′.

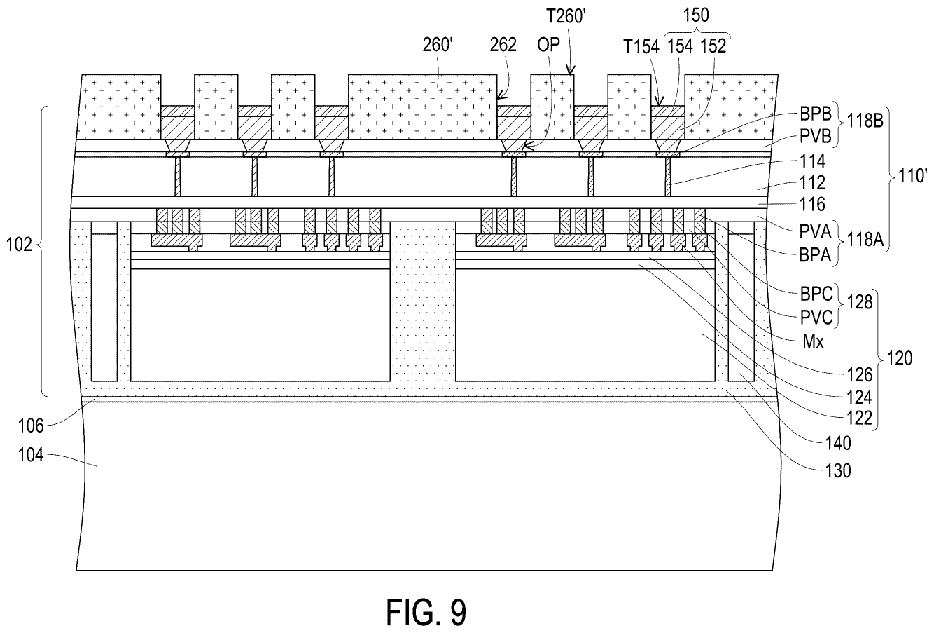

In FIG. 9, conductive terminals 150 are formed in the through holes 262 and the openings OP. The formation of the conductive terminal 150 includes depositing a first conductive material on the bonding pads BPB revealed by the through holes 262 and the openings OP through electro plating, electroless plating or the like to form a first conductor portion 152, and depositing a second conductive material on the first conductor portion 152 through sputtering, printing, CVD, or the like to form a second conductor portion 154 on the first conductor portion 152. The thickness of the thick mask layer 260′ is large so that the distal surface T154 of the second conductor portion 154 is more adjacent to the interposer wafer 110′ than the distal surface T260′ of the thick mask layer 260′. In other words, the distal surface T154 is located between the distal surface T260′ and the interposer wafer 110′ in the thickness direction.

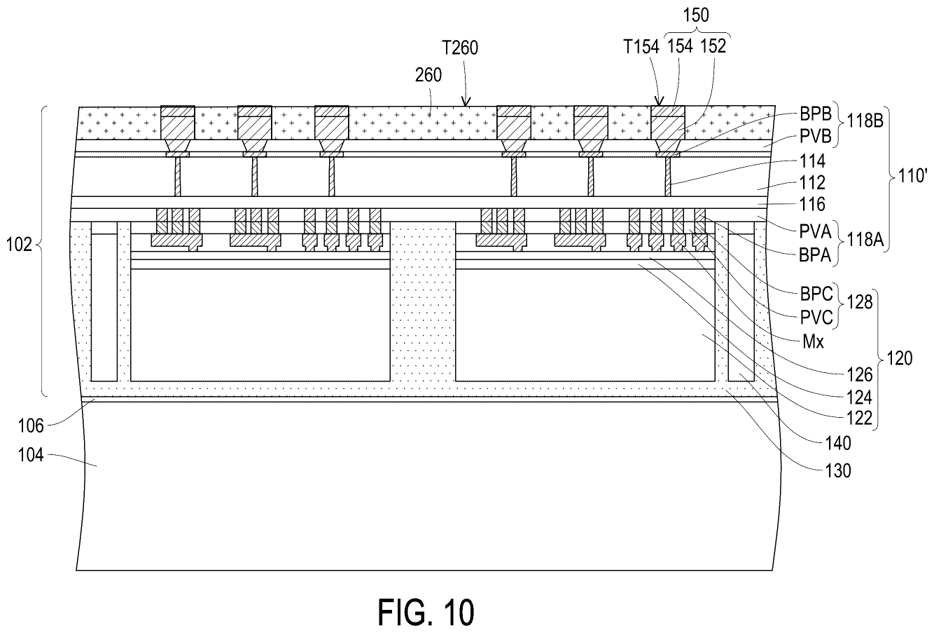

In FIG. 10, a planarization process is performed to remove a portion of the thick mask layer 260′ exceeding the second conductor portion 154 to form a first fill material layer 260. The planarization process may include grinding, chemical-mechanical polishing (CMP), or the like and be performed to reach the level of the distal surface T154 of the second conductor portion 154. Accordingly, the distal surface T260 of the first fill material layer 260 away from the interposer wafer 110′ is co-leveled with the distal surface T154 of the second conductor portion 154 away from the interposer wafer 110′. The first fill material layer 260 is disposed on the passivation layer PVB of the bonding layer 118B and surrounds the first conductor portion 152 and the second conductor portion 154. The first fill material layer 260 fills the lateral space between the conductive terminals 150 so that a flat and continuous surface is formed by the distal surface T260 of the first fill material layer 260 and the distal surface T154 of the second conductor portion 154.

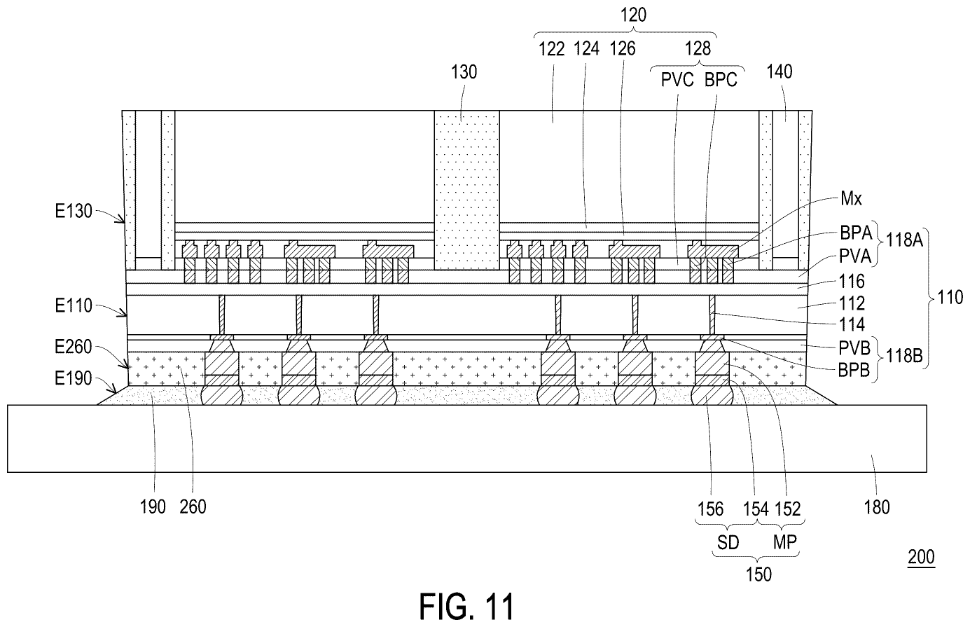

After the planarization process of FIG. 10, the processing steps described in FIGS. 4 to 6 are performed to obtain the semiconductor package 200 shown in FIG. 11. The semiconductor package 200 includes the interposer substrate 110 that is cut from the interposed wafer 110', semiconductor dies 120 bonded to and electrically connected to the interposer substrate 110, an insulation encapsulant 130 disposed on the interposer substrate 110 and laterally encapsulating the semiconductor dies 120, through insulation structures 140 extending through the insulation encapsulant 130, a package substrate 180 opposite to the semiconductor dies 120, conductive terminals 150 disposed on the interposer substrate 110 and bonded to the package substrate 180, the first fill material layer 260 disposed on the interposer substrate 110 and surrounding the conductive terminals 150, and a second fill material layer 190 disposed between the first fill material layer 260 and the package substrate 180 and surrounding the conductive terminals 150. Accordingly, the conductive terminals 150 are laterally encapsulated by the first fill material layer 260 and the second fill material layer 190.

Each of the conductive terminals 150 includes a first conductor portion 152, a second conductor portion 154 and a third conductor portion 156 sequentially stacked on the interposer substrate 110. The first conductor portion 152 and the second conductor portion 154 are formed through the processing step depicted in FIG. 9 to have a pillar-like structure. Accordingly, the first conductor portion 152 and the second conductor portion 154 form a metal pillar MP. In some embodiments, the second conductor portion 154 and the third conductor portion 156 both include a solder material so that the second conductor portion 154 and the third conductor portion 156 form a solder structure SD on the first conductor portion 152 that may not include a solder material. The first fill material layer 260 limits the shape of the metal pillar MP and thus the second conductor portion 154 though includes solder material maintains the pillar-like shape before and after the reflow process depicted in FIG. 5. Therefore, a portion of the solder structure SD, i.e. the second conductor portion 154, has a pillar-like shape and another portion of the solder structure SD, i.e. the third conductor portion 156, has a bumpy shape after the reflow process. In some embodiments, the sidewall of the third conductor portion 156 is curved to have a curvature greater than a sidewall of the second conductor portion 154 while a sidewall of the second conductor portion 154 and a sidewall of the first conductor portion 152 have similar curvature and/or may be linearly aligned. In some embodiments, the third conductor portion 156 lateral exceeds the second conductor portion 154 and is likely to have an asymmetric shape due to the deformation caused by the reflow process. Accordingly, the solder structure SD has a pillar portion and a bumpy cap over the pillar portion.

The sidewall E130 of the insulation encapsulant 130, the sidewall E110 of the interposer substrate 110 and the sidewall E260 of the first fill material layer 260 are connected continuously along a linear trace which is parallel to, or oblique to the thickness direction. In some embodiments, the sidewall E130, the sidewall E110 and the sidewall E260 may be gradually shrunk toward center in a direction directing from the interposer substrate 110 to the package substrate 180. In some embodiments, the width of the insulation encapsulant 130 is substantially identical to the width of the interposer substrate 110 at a boundary between the insulation encapsulant 130 and the interposer substrate 110. In addition, the width of the interposer substrate 110 is substantially identical to the width of the first fill material layer 260 at the boundary between the interposer substrate 110 and the first fill material layer 260. The sidewall E190 of the second fill material layer 190 extends gradually exceeding the sidewall E260 of the first fill material layer 260 in a direction directing from the interposer substrate 110 to the package substrate 180. Accordingly, an included angle is formed between the sidewall E260 and the sidewall E190. In some embodiments, a portion of the second fill material layer 190 may cover a sidewall of a lower portion of the first fill material layer 260.

In light of the above, the semiconductor package in accordance with embodiments of the disclosure includes dual layers of fill material layers to encapsulate the conductive terminals configured for bonding to the package substrate. The conductive terminal may include a solder-free first conductor portion and a solder structure formed by a second conductor portion and a third conductor portion. In addition, the solder structure of each conductive terminal is fabricated through multiple steps, and for example the second conductor portion and the third conductor portion of the conductive terminals are fabricated respectively before and after the singulation process for cutting the wafer form structure into a single package unit. During the singulation process, the second conductor portion and the first conductor portion of the conductive terminal surrounded by the first fill material layer are completely covered by the protection film. The singulation process includes, but not limits to, a laser irradiation and a die sawing and may generate cutting debris. The second conductor portion is less likely to be stained by the cutting debris doe to the well coverage of the protection film. Accordingly, the conductive terminals provide firmly bonding effect between the interposer substrate and the package substrate, which improves the yield of the semiconductor package and ensures the electric transmission quality of the semiconductor package.

In accordance with some embodiments of the disclosure, a semiconductor package including an interposer substrate; a semiconductor die bonded to a first side of the interposer substrate; a first fill material layer having a through hole; and a conductive terminal disposed in the through hole, the conductive terminal including a first conductor portion, a second conductor portion and a third conductor portion, the first conductor portion being between the second conductor portion and the interposer substrate, and the second conductor portion being between the first conductor portion and the third conductor portion, wherein a boundary between the first conductor portion and the second conductor portion is located between opposite surfaces of the first fill material. A material of the first conductor portion may be different from the second conductor portion and the third conductor portion. A material of the second conductor portion and the third conductor portion may include a solder material. A second fill material layer fills a space between the first fill material layer and the package substrate and encapsulates the third conductor portion. A material of the second fill material layer is different from a material of the first fill material layer. A width of the third conductor portion is greater than a width of the second conductor portion. A sidewall of the third conductor portion has a curvature greater than a sidewall of the second conductor portion. An insulation encapsulant surrounds the semiconductor die, wherein a sidewall of the insulation encapsulant, a sidewall of the interposer substrate and a sidewall of the first fill material layer are linearly aligned.

In accordance with some other embodiments of the disclosure, a semiconductor package includes a package substrate; an interposer substrate bonded to the package substrate; a conductive terminal disposed between the package substrate and the interposer substrate, wherein the conductive terminal comprises a solder structure; a first fill material layer disposed between the package substrate and the interposer substrate; and a second fill material layer disposed between the package substrate and the interposer substrate, wherein the first fill material layer and the second fill material layer encapsulate different portions of the solder structure. A portion of the solder structure laterally encapsulated by the first fill material layer is narrower than another portion of the solder structure laterally encapsulated by the second fill material layer. A material of the first fill material layer is different from the second fill material layer. A sidewall of the interposer substrate and a sidewall of the first fill material layer are linearly aligned. A sidewall of the second fill material layer is tapered exceeding the first fill material layer. The conductive terminal includes a first conductor portion, the solder structure is disposed on the solder structure, and a boundary between the first conductor portion and the solder structure is located between opposite surfaces of the first fill material layer. The solder structure of the conductive terminal further includes a second conductor portion encapsulated by the first fill material layer and a third conductor portion encapsulated by the second fill material layer, and the second conductor portion is disposed between the first conductor portion and the third conductor portion.

In accordance with some other embodiments of the disclosure, a method of fabricating a semiconductor package includes disposing a conductive terminal on an interposer wafer by sequentially forming a first conductor portion and a second conductor portion; forming a first fill material layer on the interposer substrate to surround the first conductor portion and the second conductor portion; cutting the interposer wafer into an interposer substrate; and bonding the interposer substrate to a package substrate through the conductive terminal. The conductive terminal may be formed by further forming a third conductor portion and the interposer substrate is bonded to the package substrate by contacting the second conductor portion to the third conductor portion. A second fill material layer is further formed after bonding the interposer substrate to the package substrate, wherein the second fill material layer is disposed between the package substrate and the first fill material layer. A material of the second fill material layer is different from the first fill material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer substrate;
a semiconductor die on the interposer substrate;
a first fill material layer having a through hole; and
a conductive terminal disposed in the through hole, the conductive terminal comprising a first conductor portion, a second conductor portion and a third conductor portion, the first conductor portion being between the second conductor portion and the interposer substrate, and the second conductor portion being between the first conductor portion and the third conductor portion, wherein a boundary between the first conductor portion and the second conductor portion is located between opposite surfaces of the first fill material.

2. The semiconductor package as claimed in claim 1, wherein a material of the first conductor portion is different from the second conductor portion and the third conductor portion.

3. The semiconductor package as claimed in claim 1, wherein a material of the second conductor portion and the third conductor portion comprises a solder material.

4. The semiconductor package as claimed in claim 1, further comprising a second fill material layer encapsulating the third conductor portion.

5. The semiconductor package as claimed in claim 4, wherein a material of the second fill material layer is different from a material of the first fill material layer.

6. The semiconductor package as claimed in claim 1, wherein a width of the third conductor portion is greater than a width of the second conductor portion.

7. The semiconductor package as claimed in claim 1, wherein a sidewall of the third conductor portion has a curvature greater than a sidewall of the second conductor portion.

8. The semiconductor package as claimed in claim 1, further comprising an insulation encapsulant surrounding the semiconductor die, wherein a sidewall of the insulation encapsulant, a sidewall of the interposer substrate and a sidewall of the first fill material layer are linearly aligned.

9. A semiconductor package comprising:
a package substrate;
an interposer substrate on the package substrate;
a conductive terminal disposed between the package substrate and the interposer substrate, wherein the conductive terminal comprises a solder structure;
a first fill material layer disposed between the package substrate and the interposer substrate; and
a second fill material layer disposed between the package substrate and the interposer substrate, wherein the first fill material layer and the second fill material layer encapsulate different portions of the solder structure.

10. The semiconductor package as claimed in claim 9, wherein a portion of the solder structure laterally encapsulated by the first fill material layer is narrower than another portion of the solder structure laterally encapsulated by the second fill material layer.

11. The semiconductor package as claimed in claim 9, wherein a material of the first fill material layer is different from the second fill material layer.

12. The semiconductor package as claimed in claim 9, wherein a sidewall of the interposer substrate and a sidewall of the first fill material layer are linearly aligned.

13. The semiconductor package as claimed in claim 9, wherein a sidewall of the second fill material layer is tapered exceeding the first fill material layer.

14. The semiconductor package as claimed in claim 9, wherein the conductive terminal comprises a first conductor portion, the solder structure is disposed on the first conductor portion, and a boundary between the first conductor portion and the solder structure is located between opposite surfaces of the first fill material layer.

15. The semiconductor package as claimed in claim 14, wherein the solder structure of the conductive terminal further comprises a second conductor portion encapsulated by the first fill material layer and a third conductor portion encapsulated by the second fill material layer, and the second conductor portion is disposed between the first conductor portion and the third conductor portion.

16. A method of fabricating a semiconductor package, comprising:
disposing a conductive terminal on an interposer wafer by sequentially forming a first conductor portion and a second conductor portion;
forming a first fill material layer on the interposer substrate to surround the first conductor portion and the second conductor portion;
cutting the interposer wafer into an interposer substrate; and
bonding the interposer substrate to a package substrate through the conductive terminal.

17. The method as claimed in claim 16, wherein the conductive terminal is formed by further forming a third conductor portion and the interposer substrate is bonded to the package substrate by contacting the second conductor portion to the third conductor portion.

18. The method as claimed in claim 16, further forming a second fill material layer after bonding the interposer substrate to the package substrate, wherein the second fill material layer is disposed between the package substrate and the first fill material layer.

19. The method as claimed in claim 18, wherein a material of the second fill material layer is different from the first fill material layer.

20. The method as claimed in claim 16, further bonding a semiconductor die on the interposer wafer.
